(19) United States
(12) Patent Application Publication
(10) Pub. No.: US 2007/0215855 A1
(43) Pub. Date: Sep. 20, 2007

(54) Wavelength tunable light emitting device by applying pressure

(75) Inventor: Hyung Dong Kang, Yongin (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/724,212

(22) Filed: Mar. 15, 2007

(30) Foreign Application Priority Data
Mar. 17, 2006 (KR) 10-2006-0024929

(51) Int. Cl. H01L 29/06

(52) U.S. Cl. 257/13

(57) ABSTRACT

A wavelength-tunable light emitting device. A resilient support substrate is provided, and a light emitting diode is formed on an area of the support substrate. The light emitting diode includes a first conductivity type semiconductor layer, an active layer and a second conductivity type semiconductor layer formed in their order. Pressure is applied to the active layer by bending the support substrate, thereby changing the energy band gap of the active layer.

### CLAIM OF PRIORITY

This application claims the benefit of Korean Patent Application No. 2006-0024929 filed on Mar. 17, 2006, in the Korean Intellectual Property Office, the disclosure of which is incorporated herein by reference.

### BACKGROUND OF THE INVENTION

1. Field of the Invention

The present invention relates to a wavelength-tunable Light Emitting Diode (LED) and, more particularly, to a wavelength-tunable light emitting device, which changes an energy band gap of an LED with pressure applied, thereby adjusting the wavelength of light emitted from the LED.

2. Description of the Related Art

In general, a Light Emitting Diode (LED) tends to emit a particular wavelength of light. Therefore, in order to realize a variety of colors, it is general to combine different colors of LEDs, i.e., semiconductor LEDs emitting red R, green G and blue B. However, combining different semiconductor LEDs not only requires a complex driving circuit, but also is subject to a loss due to color mixing.

Studies have been conducted recently on ways to tune a particular wavelength of light of an LED to another wavelength of light. FIG. 1 suggests a wavelength-tunable LED in which pressure is applied by piezoelectric layers 15 to an LED 11 emitting a particular wavelength of light, thereby adjusting an energy band gap of an active layer 11b to change the wavelength of light.

Here, in order to change the lattice constant of the LED, pressure is applied in a perpendicular direction a surface of the active layer 11b of the LED. Thus, the piezoelectric layers 15 are disposed at outer sides of first and second conductivity type clad layers 11a and 11c of the LED 11, with a rigid frame 16 surrounding the piezoelectric layers 15. When a voltage is applied to the piezoelectric layers 15, the piezoelectric layers 15 are increased in their thicknesses to apply pressure to the LED 11, which in turn increases the energy band gap of the active layer 11b. As a result, the LED emits a shorter wavelength of light than prior to being applied with pressure.

However, the prior art requires additional components like piezoelectric layers, a voltage source for applying a voltage to the piezoelectric layers and a rigid frame for conveying the pressure from the volume increase of the piezoelectric layers to the LED, to tune the wavelength of the LED, complicating a configuration of the light emitting device. Further, the rigid frame surrounds a considerable portion of the LED, which degrades the light emission efficiency.

### SUMMARY OF THE INVENTION

The present invention has been made to solve the foregoing problems of the prior art and therefore an aspect of the present invention is to provide a wavelength-tunable Light Emitting Diode (LED) which adjusts an energy band gap of an active layer thereof by bending a substrate to apply pressure to a semiconductor LED, thereby changing the wavelength of light.

According to an aspect of the invention, the invention provides a wavelength-tunable light emitting device which includes: a resilient support substrate; and a light emitting diode formed on an area of the support substrate, the light emitting diode comprising a first conductivity type semiconductor layer, an active layer and a second conductivity type semiconductor layer formed in their order, wherein the active layer changes an energy band gap in response to pressure applied as the support substrate is bent.

Preferably, the support substrate is made of one selected from the group consisting of Si, GaAs, GaN and sapphire. In addition, the support substrate may be a metal plate.

The wavelength-tunable light emitting device may further include a metal plate attached under the support substrate to complement the fragility of the support substrate.

Preferably, the support substrate has one end fixed to a support block so as to be bent by the force acting at the other end thereof.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic view illustrating a wavelength-tunable light emitting device according to the prior art;

FIG. 2 is a schematic view illustrating a wavelength-tunable light emitting device according to the present invention;

FIGS. 3(a) and (b) are schematic views illustrating an embodiment of the present invention; and

FIG. 4 is a graph showing the relationship between the curvature radius of a bent substrate and the pressure applied to an active layer in the wavelength-tunable light emitting device according to an embodiment of the present invention.

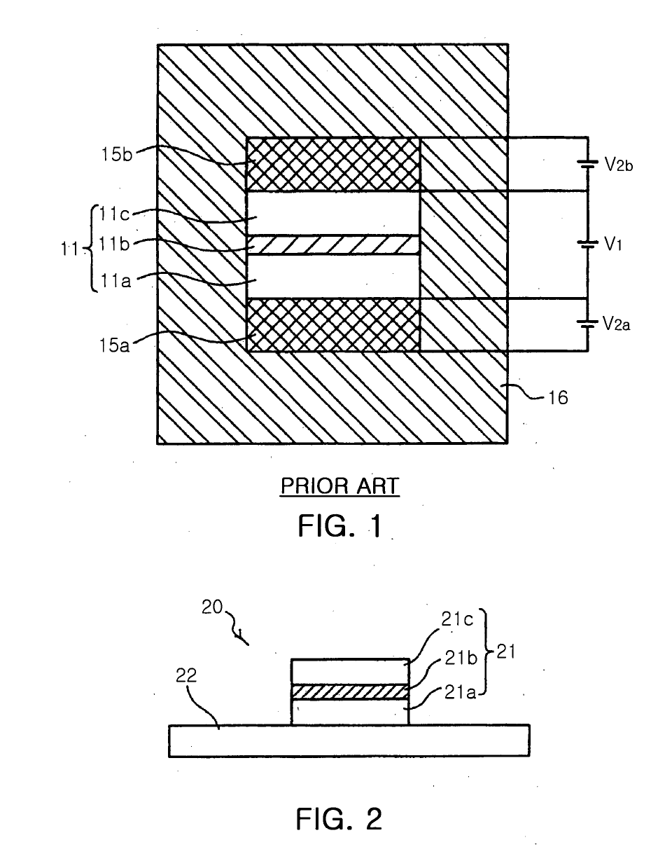

### DETAILED DESCRIPTION OF THE PREFERRED EMBODIMENT

Exemplary embodiments of the present invention will now be described in detail with reference to the accompanying drawings.

FIG. 2 is a schematic view illustrating a wavelength-tunable light emitting device according to the present invention.

Referring to FIG. 2, the wavelength-tunable light emitting device 20 according to the present invention includes a substrate 22 and a light emitting diode chip 21 disposed on a surface of the substrate.

The substrate 22 is resilient to the degree that it can be bent by physical force applied from an external source. Preferably, the substrate 22 is made of a rigid body with sufficient rigidity that allows effective conveyance of the pressure to the active layer 21b. In addition, it is preferable that the substrate 22 has a rigid body that can maintain a bent posture once after it is bent with a predetermined force while no additional external force is being applied.

In order for the pressure from-bending of the substrate 22 to be conveyed to the active layer 21b, the LED chip 21 should be bonded strongly to the substrate 21. This prevents the LED chip 21 from being separated from the substrate 22 when the substrate 22 is bent. Preferably, the LED chip 21 can be grown on the substrate 22 to be formed integrally with the substrate 22.

For example, the support substrate 22 can be an LED growth substrate selected from a silicon (Si) substrate, a GaAs substrate, a GaN substrate and a sapphire substrate. However, sufficient rigidity may not be obtained to sustain bending and fragility may occur when only a Si substrate, a GaAs substrate, a GaN substrate or a sapphire substrate is used. Thus, alternatively, a metal plate may be attached under the substrate.

To apply pressure to the substrate 22, with the substrate 22 having one end fixed to a support block, a force can be applied to an upper surface or an undersurface of the other end of the substrate 22 in a perpendicular direction to the active layer 21b. At this time, even if the pressure is applied to one end of the substrate 22, the entire substrate will not be bent uniformly in a circular shape. Only the central portion of the substrate 22 will be bent in a circular shape. Therefore, the central portion of the substrate 22 can be made thinner than the opposed portions thereof to enhance the bending property. At this time, it is preferable that the LED 21 is disposed on an upper surface of the central portion of the substrate 22, which mainly bends, so as to be affected maximally by the bending of the substrate.

Alternatively, force can be applied to the opposed ends of the substrate 22 horizontally toward the central portion thereof to bend the substrate 22. In this case, a third force can be applied to the central portion of the substrate upward or downward in a perpendicular direction to the substrate, thereby determining the direction of the bending of the substrate.

In general, the energy band gap of the semiconductor material has a pressure dependence of about 3 to 6 meV/Kbar. Therefore, applying about 100 Kbar can induce about 100 to 300 nm of wavelength tuning, realizing a variety of colors of visible rays.

According to such pressure dependence, the energy band gap tends to increase with the increase of pressure in the case of a general semiconductor material. Thus, the wavelength of light of the LED tends to be shortened by the increase in the pressure. Therefore, it is preferable for an LED to have a wavelength of about 500 nm to 800 nm without the pressure being applied, to realize a full spectrum of colors.

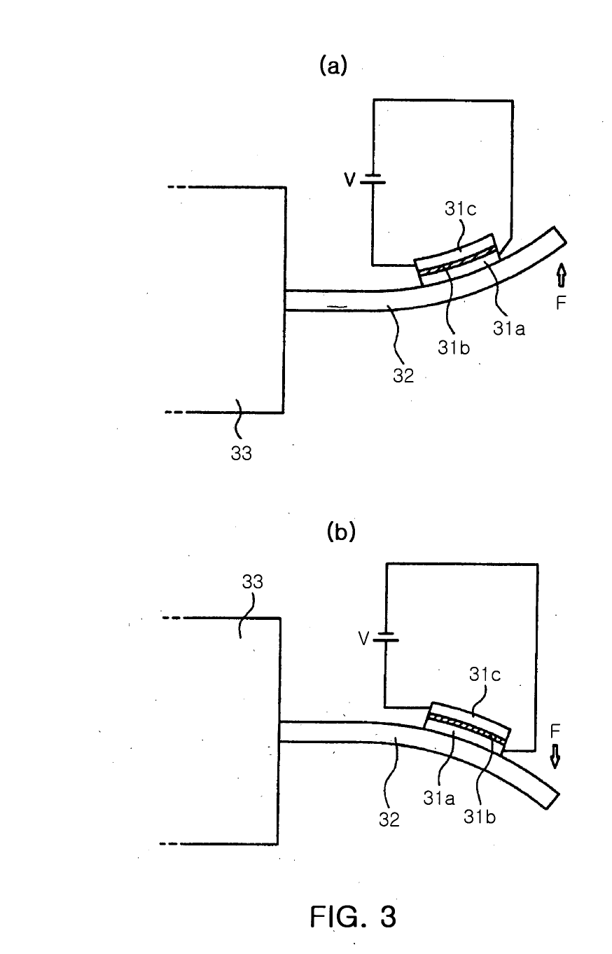

FIGS. 3(a) and (b) are schematic views illustrating the bending of the substrate by applying pressure to the substrate according to an embodiment of the present invention.

In FIG. 3(a), while the substrate 32 has one end fixed to a support block 33, a force F is applied to an undersurface of the other end of the substrate so that the LED chip 31 is positioned at the inner side of the substrate 32.

As shown in FIG. 3(a), the pressure affects the active layer 31b of the LED chip 31 positioned at the inner side of the substrate 32 in a horizontal direction (parallel to the active layer surface), and thereby the energy band gap of the active layer 31b is widened to emit a short wavelength of light.

In FIG. 3(b), while the substrate 32 has one end fixed to a support block 33, a force F is applied to an upper surface of the other end of the substrate so that the LED chip 31 is positioned at the outer side of the bent substrate 32.

As shown in FIG. 3(b), due to the bending of the substrate 32, tensile force affects the active layer 31b of the LED chip 31 positioned at the outer side of the substrate 32 in a horizontal direction (parallel to the active layer surface), and thereby the energy band gap of the active layer 31b is narrowed to emit a long wavelength of light.

As shown in FIGS. 3(a) and 3(b), the portion of the substrate in contact with LED chip 31 is mainly bent to apply pressure to the LED chip 31. Therefore, the substrate can be configured to have different thicknesses in the portion of the substrate where the LED chip 31 is not grown and the portion where the LED chip 31 is grown, thereby varying the degree of bending of the substrate 32.

The range of the change in the wavelength due to the pressure applied to the active layer 31b can vary according to an electric field (or a bias voltage applied to the LED chip 31) applied to the active layer 31b. For example, the wavelength may decrease with pressure increase at a particular bias voltage whereas the wavelength may increase with pressure increase at another bias voltage.

The change in the wavelength according to the applied pressure can be measured from a sample of the wavelength-tunable light emitting device fabricated with the configuration as shown in FIG. 3. According to the conventional technologies related to the current embodiment, the pressure a applied to the active layer 31b is calculated by the measurement of the curvature radius R of the bent substrate 32, where the applied pressure a and the curvature radius R satisfy the following condition.

σ=Yh/2R

In the above equation, Y represents Young's modulus and h represents the thickness of the substrate.

As shown in the above equation, the pressure applied to the active layer is in inverse proportion to the curvature radius of the bending substrate, and in direct proportion to the thickness of the substrate. Therefore, the pressure applied to the active layer increases with a smaller curvature radius of the substrate and with a greater thickness of the substrate. It is suitable to adjust the thickness and the curvature radius of the substrate in consideration of the products to which the light emitting device is applied.

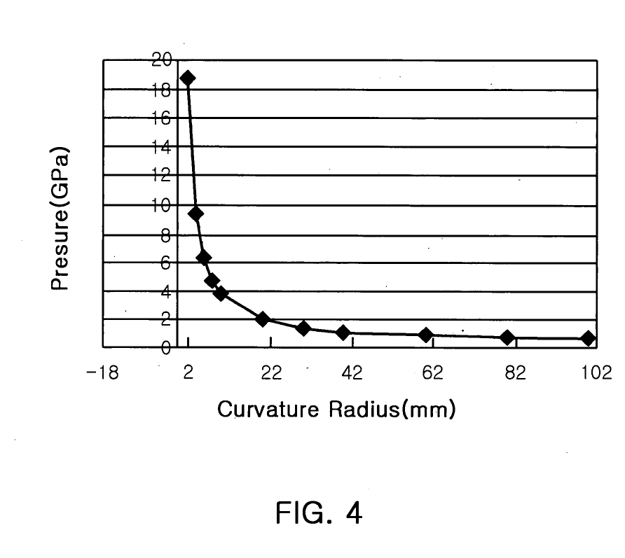

FIG. 4 is a graph illustrating the pressure applied to the active layer in accordance with the curvature radius.

Here, a substrate having a thickness of 0.5 mm was used, where a pressure of 20 Gpa can be obtained at a curvature radius of about 2 mm, which equals the wavelength conversion effect of about 200 nm. For reference, 1 MPa equals 10 bar.

The change of the pressure in accordance with the curvature radius is not linear and is significant in the range of the curvature radius of 2 mm to 22 mm. That is, at the curvature radius of the substrate of 2 mm, the applied pressure is about 20 MPa, and at the curvature radius of the substrate of 22 mm, the applied pressure precipitously decreases to 2 GPa. But afterwards, even if the curvature radius increases by multiples, the corresponding pressure does not decrease as much.

The same applies to the case when the substrate is bent the other direction and the same magnitude of tensile force is at work.

As shown, the pressure applied to the active layer is affected sensitively by the change in the curvature radius, and thus the curvature radius can be mechanically adjusted to control the light wavelength of the LED.

Such a relationship between the curvature radius and the pressure can be affected not only by the thickness of the substrate but also by the bias voltage applied to the LED chip.

The present invention does not specifically disclose the relationship between the thickness of the substrate and the curvature radius, applied pressure, change of the energy band gap and wavelength, but a person with ordinary skill in the art will be able to derive a necessary data.

According to the present invention as set forth above, particular light of a single finished LED can be adjusted by bending a substrate. When applied to a full-color display, the curvature radius of the substrate can be mechanically adjusted to realize a variety of colors.

Furthermore, according to the present invention, the wavelength-tunable light emitting device can be fabricated with a reduced number of components and can have enhanced light emission efficiency.

While the present invention has been shown and described in connection with the exemplary embodiments, it will be apparent to those skilled in the art that modifications and variations can be made without departing from the spirit and scope of the invention as defined by the appended claims.

What is claimed is:

1. A wavelength-tunable light emitting device comprising:
a resilient support substrate; and
a light emitting diode formed on an area of the support substrate, the light emitting diode comprising a first conductivity type semiconductor layer, an active layer and a second conductivity type semiconductor layer formed in their order,
wherein the active layer changes an energy band gap in response to pressure applied as the support substrate is bent.

2. The wavelength-tunable light emitting device according to claim 1, wherein the support substrate comprises one selected from the group consisting of Si, GaAs, GaN and sapphire.

3. The wavelength-tunable light emitting device according to claim 2, further comprising a metal plate attached under the support substrate.

4. The wavelength-tunable light emitting device according to claim 1, wherein the support substrate comprises a metal plate.

5. The wavelength-tunable light emitting device according to claim 1, wherein the support substrate has one end fixed to a support block so as to be bent by the force acting at the other end thereof.
